(19) United States
(12) Patent Application Publication
(10) Pub. No.: US 2013/0119999 A1
(43) Pub. Date: May 16, 2013

(54) Specimen Testing Device and Method for Creating Absorbed Current Image

(71) Applicants: Tomoharu Obuki, Hitachinaka (JP); Mitsuhiro Nakamura, Hitachinaka (JP); Yasuhiko Nara, Hitachinaka (JP); Tohru Ando, Tokyo (JP)

(72) Inventors: Tomoharu Obuki, Hitachinaka (JP); Mitsuhiro Nakamura, Hitachinaka (JP); Yasuhiko Nara, Hitachinaka (JP); Tohru Ando, Tokyo (JP)

(73) Assignee: Hitachi High-Technologies Corporation, Tokyo (JP)

(21) Appl. No.: 13/806,561

(22) PCT Filed: Jul. 20, 2011
(86) PCT No.: PCT/JP2011/066400

§ 371 Date: Dec. 21, 2012

(30) Foreign Application Priority Data
Jul. 29, 2010 (JP) 2010-170371

(51) Int. Cl. G01R 31/265

(52) U.S. Cl. CPC G01R 31/2653
USPC 324/501

(57) ABSTRACT

Proposed is a technique of emphasizing a change in absorbed current obtained from a faulty part in a wiring section as a testing target more than in other parts of the wiring section. A specimen testing device is configured to output an image of absorbed current output from two probes during scanning of an electron beam so as to be operatively associated with the scanning of the electron beam and includes the following mechanism. When a faulty part of a wiring section on the specimen side with which two probes are in contact is irradiated with an electron beam, the resistance value at the faulty part changes more than that of irradiation of a normal wiring section with the electron beam. Such a change in resistance value is detected as a change in ratio between a resistance value of the wiring section specified by the two probes and a known resistance value. With this method, an absorbed current image corresponding to the faulty part can be made easily distinguishable from an absorbed current image of other parts of the wiring section.

### TECHNICAL FIELD

The present invention relates to a specimen testing device to test semiconductors and other specimens, and a method for creating an absorbed current image using the device. For instance, the present invention relates to a technique of facilitating the identification of an electric faulty part included in wiring (conductor) as a test target.

### BACKGROUND ART

For testing of a semiconductor specimen with a circuit pattern formed on a surface thereof, it is important to specify a faulty part. Meanwhile the tendency of finer devices these days makes it difficult to identify a faulty part. As a result, faulty analysis requires enormous time. Therefore OBIRCH (Optical Beam Induced Resistance Change) or EB (Electron Beam) testers and other analyzers are currently used for faulty analysis of this type. In the field of faulty analysis of wiring, another technique receiving attention is to irradiate a semiconductor specimen with an electron beam and analyze current absorbed by the wiring or a secondary signal (secondary electrons or reflected electrons) emitted from the semiconductor specimen for imaging. A distribution image of a signal (absorbed current image) obtained on the basis of the current (absorbed current) absorbed by the wiring is called an electron beam absorbed current (EBAC) image.

The following describes a conventional technique relating to the EBAC. Patent Document 1, for example, discloses an absorbed current detector configured to irradiate a wiring pattern on the surface of a specimen with a charged particle beam and measure absorbed current flowing through two probes a and b that are in contact with the wiring pattern. The detector of Patent Document 1 has a feature of giving the absorbed current flowing through the probes a and b to a current/voltage converter via an input resistance for output voltage control having a predetermined resistance value. Meanwhile, Patent Document 2 discloses a technique of varying a temperature of a specimen during the creation of an absorbed current image and acquiring a differential image for absorbed current image created at each temperature, thus identifying a faulty part.
Patent Document 1: JP Patent Publication (Kokai) No. 2008-203075 A
Patent Document 2: JP Patent Publication (Kokai) No. 2009-252854 A

### DISCLOSURE OF THE INVENTION

### Problem to be Solved by the Invention

The detector disclosed in Patent Document 1 converts absorbed current into voltage using a current/voltage converter. This means that the absorbed current depends on resistance only of the wiring pattern. That is, the detector can acquire information on absorbed current in a steady state only, and cannot detect a peculiar variation point generated halfway through the wiring pattern.

The detector disclosed in Patent Document 1 further creates an absorbed current image by plotting detected signals of the absorbed current while scanning an electron beam. The detector, however, uses a grounding potential (GND) as a reference potential for the detected signals of the absorbed current. Therefore compared with the case of using a differential amplifier, the measurement dynamic range inevitably becomes narrower with reference to the detected signals of the absorbed current. Especially when the faulty part has a small resistance value, an electron beam as a signal source has to be intensified in order to increase a change of the detected signal at the faulty part. When the energy of the electron beam is increased, however, since current flows through the faulty part a lot, the specimen itself may break before the faulty part is displayed.

Meanwhile, the device disclosed in Patent Document 2 acquires absorbed current images under different temperature conditions by heating or cooling the specimen as a whole. Thus, the device can observe a variation in electric characteristics generated with a temperature change of the specimen as a whole. The technique of this device, however, cannot change the temperature locally. This means that a variation in electronic characteristics due to a local temperature change of the faulty part or a surrounding thereof cannot be observed. Accordingly, the device of Patent Document 2 also has a difficulty in identifying a faulty part.

In view of this, it is an object of the present inventors to provide a technique of allowing an absorbed current-detecting type specimen testing device to easily detect a local change of absorbed current.

### Means for Solving the Problem

The present inventors propose a device configuration that is preferably applicable to a specimen testing device configured to scan a tested range of a specimen with an electron beam while bringing two probes into contact with the specimen and to output a distribution image of absorbed current detected from the two probes.

For instance, a proposed device configuration may include: a bridge circuit that uses, as unknown resistance, a wiring section on the specimen side specified by an electric contact of at least two probes with the specimen; a differential amplifier that receives, as an input, a signal from two points on the bridge circuit where an equipotential appears in a balanced state; and an image processing unit that outputs an absorbed current image while letting a differential output signal of the differential amplifier operatively associated with scanning of an electron beam to the specimen.

In this device configuration, the irradiation of a wiring section with an electron beam causes an absorbed current to flow from the probes to the bridge circuit to change a balanced state of the bridge circuit. Such a change from the balanced state is amplified by the differential amplifier, whereby an absorbed current image is created. The device is configured to further detect a change of local resistance value or current value when a faulty part is irradiated with an electron beam as a change of resistance ratio of the bridge circuit. Therefore the device can generate an absorbed electron image so that the faulty part is emphasized in the wiring section.

For instance, another proposed device configuration may include: a resistance connected in series with a wiring section on the specimen side specified by an electric contact of at least two probes with the specimen; a differential amplifier detecting a signal appearing at a connection midpoint between the resistance and the wiring section; and an image processing unit that outputs an absorbed current image while letting a differential output signal of the differential amplifier operatively associated with scanning of an electron beam to the specimen.

In this device configuration, the irradiation of a wiring section with an electron beam causes an absorbed current to flow from the probes to the resistance to change the resistance from the initial state. Such a change from the initial state is amplified by the differential amplifier, whereby an absorbed current image is created. The device is configured to further detect a change of local resistance value or current value when a faulty part is irradiated with an electron beam as a change of resistance ratio relative to the resistance connected in series. Therefore the device can generate an absorbed electron image so that the faulty part is emphasized in the wiring section.

### Effects of the Invention

According to the present invention, an absorbed electron image can be obtained so that a faulty part in a wiring section is emphasized more than in other parts of the wiring section. As a result, the accuracy of identification of the faulty part or the efficiency for the measurement of faulty analysis can be improved.

### BRIEF DESCRIPTION OF THE DRAWINGS

FIG. 1 schematically shows a configuration of a specimen testing device as one embodiment of the present invention.

FIG. 2 shows an exemplary configuration of a semiconductor testing device including the configuration corresponding to FIG. 1.

FIG. 3 schematically shows a configuration of a specimen testing device as another embodiment of the present invention.

FIG. 4 shows an exemplary configuration of a semiconductor testing device including the configuration corresponding to FIG. 3.

### MODE FOR CARRYING OUT THE INVENTION

The following describes embodiments of the present invention, with reference to the drawings.

### Embodiment 1

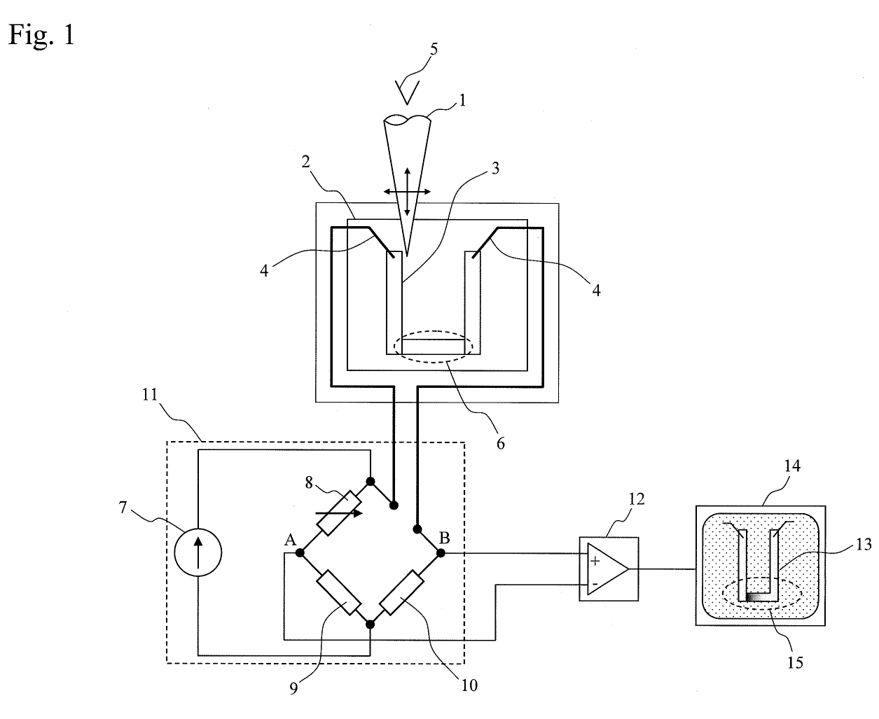

FIG. 1 schematically shows an exemplary configuration of a specimen testing device. The specimen testing device according to this embodiment corresponds to a type using a differential amplifier to generate an electron beam absorbed current (EBAC) image among the aforementioned detection mechanisms.

The device according to this embodiment irradiates a specimen 2 with a primary electron beam 1 from an electron beam source 5. The specimen 2 includes a wiring pattern 3 formed therein. In this specification, the wiring pattern 3 includes not only a wiring pattern (this may be called a “net”) exposed at the surface of the specimen 2 but also a wiring pattern formed in a lower-layer plane. Further the wiring pattern 3 includes not only a wiring pattern formed at a single layer but also a wiring pattern three-dimensionally connected across multiple layers. Moreover the wiring pattern 3 in this specification includes not only a wiring pattern as designed but also a wiring pattern connected accidentally connected by a short-circuit fault. FIG. 1 briefly depicts the wiring pattern 3.

The device according to this embodiment at least includes two probes 4. For testing, the device brings the probes 4 into contact with both ends of the wiring pattern 3 as a testing target or two pads thereof, respectively. When the probes 4 come into contact at a predetermined position, the surface region of the specimen 2 including the wiring pattern 3 is scanned with the primary electron beam 1. Irradiated the wiring pattern 3 (including a faulty part 6 in the wiring pattern 3) with the primary electron beam 1, electrons of the primary electron beam 1 enter into the wiring pattern 3. They are absorbed current. The absorbed current is taken out by the probes 4. Normally EBAC is generated as a distribution image of signals (absorbed current signals) detecting the absorbed current. When a region other than the wiring pattern 3 is irradiated with the primary electron beam 1, the output from the probes 4 does not include absorbed current.

In the case of the device according to this embodiment, the wiring pattern 3 as the detection target is dealt with as unknown resistance making up a bridge circuit 11. That is, wiring is performed so that the wiring pattern 3 (unknown resistance) having both ends at contact points with the two probes 4 forms one series circuit of a pair of series circuits making up the bridge circuit 11. In the case of FIG. 1, the wiring pattern 3 is connected in series with a fixed resistance 10 having a known resistance value. The other series circuit of the bridge circuit 11 is made up of a variable resistance 8 with a variable resistance value and a fixed resistance 9 having a known resistance value. Needless to say, when the two probes 4 are not in contact at a predetermined position of the specimen 2, the series circuit including the fixed resistance 10 becomes equivalent to a circuit with a line disconnected, so that the bridge circuit 11 does not function as a bridge circuit.

In the case of this embodiment, a constant current source 7 is connected so that a connection midpoint between one side of a leading wiring extending from the root of one probe 4 and the variable resistance 8 is a flow-in side of the current and a connection midpoint between the fixed resistances 9 and 10 becomes a flow-out side of the current. That is, the constant current source 7 is connected so that the variable resistance 8-arranged side becomes a current branch point and the fixed resistance 9-arranged side becomes a current merging point. When the two probes 4 come into contact at a predetermined position of the specimen 2, the closed circuit is completed, and the current from the constant current source 7 branches off to two series circuits to flow therethrough. Although FIG. 1 shows the example of the constant current source 7 connected, a voltage source may be connected in the configuration instead of the constant current source 7.

The bridge circuit 11 has one output end A at the connection midpoint between the variable resistance 8 and the fixed resistance 9, and has the other connection end B at the connection midpoint between unknown resistance (resistance of the wiring pattern 3) and the fixed resistance 10. That is, two points having the same electric potential when the bridge circuit 11 is in a balanced state are set as the output ends. In the case of FIG. 1, the connection midpoint between the variable resistance 8 and the fixed resistance 9 is connected to an inverting input end of a differential amplifier 12, and the connection midpoint between (the resistance of the wiring pattern 3) and the fixed resistance 10 is connected to a non-inverting input end of the differential amplifier 12. At the output end of the differential amplifier 12 appears a differential output signal that is a signal generated in accordance with the current flowing through the fixed resistances 9 and 10 of the bridge circuit 11 or voltage generated across the fixed resistances 9 and 10 and is subjected to differential-amplification. As described later, when the bridge circuit 11 is in a balanced state, the differential output signal will be zero, and when the wiring pattern 3 is irradiated with the primary electron beam 1, the differential output signal will not be zero.

The differential output signal is converted into a brightness value while being associated with a scanning position of the primary electron beam 1 by an image processing unit not illustrated. FIG. 1 shows the state where a display 14 displays an absorbed current image 13 corresponding to the wiring pattern 3. In this drawing, a region surrounded by the dotted line in the absorbed current image 13 is an absorbed current image 15 corresponding to the faulty part 6 of the wiring pattern 3. As can be understood from the drawing, the displaying is performed so that a change in brightness of the absorbed current image 15 becomes remarkable more than at the wiring pattern 3 other than the failure part 6.

Next, an exemplary operation for testing using the specimen testing device according to Embodiment 1 is described. The following description assumes the state where the probes 4 are already in contact at a predetermined position of the specimen 2.

Firstly, an operation to adjust the bridge circuit 11 to a balanced state is described. During this operation, irradiation with the primary electron beam 1 is not performed. Accordingly, through the series circuit including the variable resistance 8 and the fixed resistance 9 and through the series circuit including the wiring pattern 3 (unknown resistance) and the fixed resistance 10 flows current supplied from the constant current source 7 only. Since the resistance value of the wiring pattern 3 is unknown, the bridge circuit 11 in the initial state is not in a balanced state. Therefore at the output end of the differential amplifier 12 appears a non-zero differential output signal. This differential output signal is monitored by a resistance controller not illustrated and the resistance value of the variable resistance 8 is variably-controlled so that the differential output signal becomes zero. That is, the resistance value of the variable resistance 8 is variably-controlled so that there is no electric potential difference between the output ends A and B of these series circuits.

Next, an operation after starting of the testing is described. Even after starting of the testing, irradiation of a region other than the wiring pattern 3 with the primary electron beam 1 obviously keeps the balanced state of the bridge circuit 11. Firstly, the following describes the case where a part of the wiring pattern 3 other than the faulty part 6 is irradiated with the primary electron beam 1. In this case, current (absorbed current) due to electrons entering into the wiring pattern 3 from the primary electron beam 1 are divided in accordance with the resistance value of the wiring pattern 3 from the irradiation point of the primary electron beam 1 to the pair of the probes 4. The current after the division is superimposed to the current flowing through the bridge circuit 11 in the balanced state.

Herein, a signal corresponding to a part of the divided absorbed current is given to a non-inverting input end of the differential amplifier 12, and a signal corresponding to a part of the remaining absorbed current is given to the inverting input end of the differential amplifier 12 via the variable resistance 8. That is, to the differential input end of the differential amplifier 12 is given one corresponding to the variation of the signal due to the absorbed signal. More specifically, a differential signal (not-zero) corresponding to a difference in current flowing through the fixed resistances 9 and 10 or a difference in voltage generated across the fixed resistances 9 and 10 is input to the differential amplifier 12. As a result, on coordinate points corresponding to the irradiation position with the primary electron beam 1 in the display screen of the display 14, a bright point with a brightness value different from those in the region other than the wiring pattern 3 will be displayed. Thus, the wiring pattern 3 is displayed on the screen.

Next, the following describes the case where the faulty part 6 in the wiring pattern 3 is irradiated with the primary electron beam 1. Generally the faulty part 6 has a resistance value different from that of a normal part of the wiring pattern 3, or is made of a different type of metal. The following describes the operation for each of various structures of the faulty part 6 that are irradiated with the primary electron beam 1.

Firstly, the operation in the case where the faulty part 6 has a resistance value different from a normal part of the wiring pattern 3 is described. Causes assumed for the fault include having a higher resistance value than normal parts (high-resistance fault) and a lower resistance value than normal parts (low-resistance fault).

In any case, the faulty part 6 is heated by thermal energy of the primary electron beam 1. Accordingly the resistance value of the faulty part 6 increases temporarily. In addition, the faulty part 6 is a local part, and does not have continuity with the resistance values of preceding and subsequent wiring sections. Therefore, compared with the case of irradiation of a normal region of the wiring pattern 3 with the primary electron beam 1, a change in resistance value of the faulty part 6 greatly influences on the flow (resistance value) of the absorbed current.

The following describes this phenomenon in more details. For manufacturing of semiconductor devices, it is very rare that the faulty part 6 has the same resistance value and shape as those of the wiring pattern 3. Accordingly, the faulty part 6 will have a wiring width thinner or thicker than that of the wiring pattern 3. When the faulty part 6 is thicker than the wiring pattern 3, the faulty part 6 is easily observable because the faulty part 6 appears thicker than the wiring pattern 3. On the other hand, when the faulty part 6 is thinner than the wiring pattern 3, the faulty part 6 has smaller thermal capacity than that of the wiring pattern 3. Accordingly, irradiated with the primary electron beam 1, the faulty part 6 will have a larger change in resistance value than that of the wiring pattern 3. When the faulty part 6 is made of metal different in type from the wiring pattern 3, since the faulty part 6 has smaller thermal capacity, the Seebeck effect when irradiated with the primary electron beam 1 will be larger than in the wiring pattern 3. Herein, the Seebeck effect is a phenomenon where a difference in electric potential occurs at a jointing part of different types of metal, the electric potential being proportional to temperatures. That is, a difference in resistance value of the faulty part 6 occurs between the case of the faulty part 6 irradiated with the primary electron beam 1 and the case of the faulty part 6 not irradiated with the primary electron beam 1 (the case of the wiring pattern 3 irradiated with primary electron beam 1).

Meanwhile, the value of current flowing through the wiring pattern as a whole is subjected to restrictions of the resistance value of the faulty part 6 compared with the case including the wiring pattern 3 only (the case free from the failure part 6). Therefore when irradiation of the faulty part 6 with the primary electron beam 1 causes an even slight change in resistance of the faulty part 6, a change will occur in the amount of absorbed current flowing through the faulty part. Such a change in the amount of absorbed current is the same as in the change in current flowing through the wiring pattern as a whole, and therefore has the same effect as in the change in resistance value of the wiring pattern as a whole.

Then, in the case of this embodiment, an absorbed current image is generated using a detection signal where the change in resistance ratio in the bridge circuit 11 is emphasized.

Actually a differential signal occurring when the faulty part 6 is irradiated with the primary electron beam 1 varies with reference to a differential signal obtained from other regions of the wiring pattern 3. Therefore there appears a clear difference in brightness (contrasting difference) between the region of the faulty part 6 and other regions of the wiring pattern 3 on an absorbed electron image displayed on the display 14. That is, the faulty part 6 is displayed in an emphasis manner compared with other regions of the wiring pattern 3. This means that identification of the faulty part 6 on the screen becomes easier.

Next, the case where a material of the faulty part 6 is different from that of other regions of the wiring pattern 3, i.e., the case where the faulty part 6 is made of a different type of metal is described. For instance, a short-circuit fault is assumed. As described above, the Seebeck effect occurs at a jointing part of different types of metal. Therefore, when the faulty part 6 is heated by irradiation with the primary electron beam 1 and increases the temperature, then an electric potential difference at the part of the faulty part 6 increases more. That is, between the case where other regions of the wiring pattern 3 are irradiated with the primary electron beam 1 and the case where the faulty part 6 is directly irradiated with the primary electron beam 1 changes greatly an electric potential difference at the region of the faulty part 6. This means that irradiation of the faulty part 6 with the primary electron beam 1 changes the flowing (resistance value) of the absorbed current in the wiring pattern 3. That is, the resistance ratio in the bridge circuit 11 changes. Therefore, the magnitude of the differential signal given to the differential amplifier 12 via the bridge circuit 11 will be different between the case where the faulty part 6 is irradiated with the primary electron beam 1 and the case where other regions of the wiring pattern 3 are irradiated with the primary electron beam 1. Therefore, the absorbed electron image displayed on the display 14 has a clear brightness difference (contrasting difference) between the region of the faulty part 6 and other regions of the wiring pattern 3. That is, the faulty part 6 can be displayed in an emphasized manner compared with other regions of the wiring pattern 3. This means easy identification of the faulty part 6 on the display.

Although FIG. 1 shows only one faulty part 6 in the wiring pattern 3, the actual specimen 2 may have multiple faulty parts 6 on the wiring pattern 3. For the faulty parts 6 having the same cause, the same reaction will occur by the irradiation with the primary electron beam 1. Therefore the aforementioned contrasting difference will occur corresponding to the number of the faulty parts 6 existing on the wiring patter 3 between the faulty part 6 and other regions of the wiring pattern 3. That is, scanning once with the primary electron beam 1 enables simultaneous detection of multiple faulty parts 6.

In the case of this embodiment, a differential input greatly changes at a boundary part between the faulty part 6 and the wiring pattern 3 surrounding thereof. Using this property, the effect of facilitating the identification of the faulty part 6 existing at a lower layer wiring can be expected as well. Typically, since there is less influence on the wiring pattern 3 located close to the surface of the specimen from the scattering of the primary electron beam 1, the outline of the wiring pattern 3 can be easily detected. On the other hand, as the wiring pattern 3 as a testing target becomes away from the surface of the specimen (the disposed position becomes deeper), the outline of the wiring pattern 3 tends to become blurred. Therefore in the case of a conventional device, even when the presence of a short-circuit fault can be found based on whether the wiring pattern 3 that should not be displayed is displayed or not, it is still difficult to identify the faulty part 6. Using the specimen testing device according to this embodiment, however, the faulty part 6 can be displayed distinguishable from the wiring pattern 3, and therefore the faulty part 6 existing at a lower layer wiring can be easily identified.

The above describes the embodiment where a difference of the faulty part 6 from other regions of the wiring pattern 3 is represented by a contrasting difference. Instead, the difference may be represented using a different display color. Further signal processing may be added by an image processing unit not illustrated so that a difference in detected signal between the faulty part 6 and other regions of the wiring pattern 3 is emphasized. For instance, in the region detected as the wiring pattern 3, a region with a detected signal changing by a threshold or more with reference to the adjacent regions may be detected as a boundary of the failure part 6.

### Embodiment 2

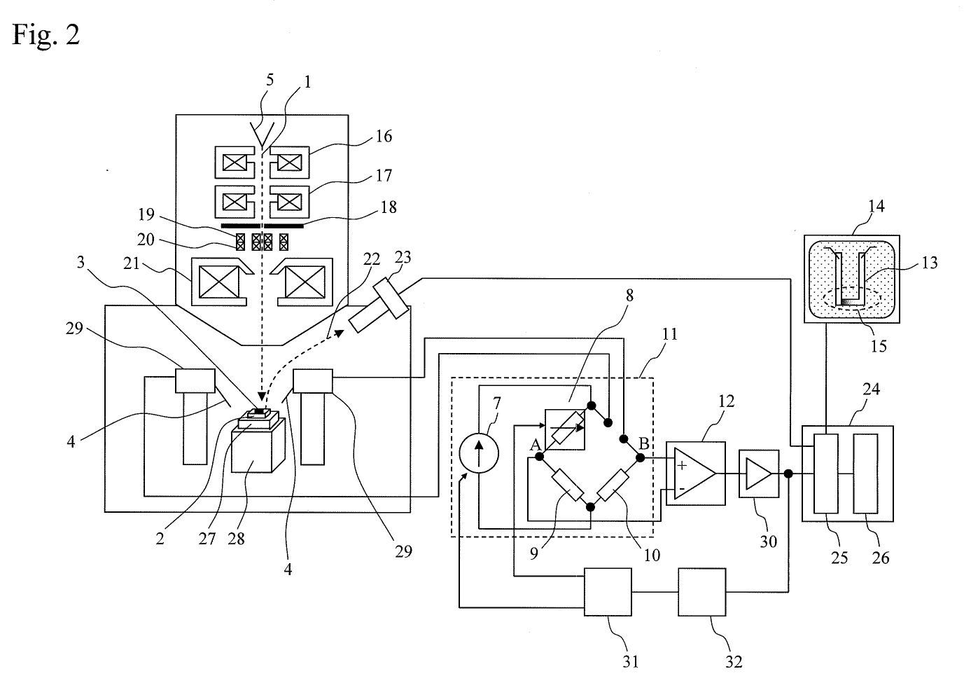

FIG. 2 shows an exemplary configuration of a semiconductor testing device including the specimen testing device according to Embodiment 1. The semiconductor testing device according to this embodiment includes an electron beam irradiation optical system enabling irradiation with an electron beam. The electron beam irradiation optical system includes an electron beam source 5, condenser lenses 16, 17, a diaphragm 18, a scanning deflector 19, an image shift deflector 20 and an objective lens 21. With this configuration, the primary electron beam 1 emitted from the electron beam source 5 is applied to a specimen 2 via the condenser lenses 16, 17, the diaphragm 18, the scanning deflector 19, the image shift deflector 20 and the objective lens 21. At this time, the primary electron beam 1 is scanned on the surface of the specimen 2 by the scanning deflector 19 or the like.

From a region of the surface of the specimen 2 that is irradiated with the primary electron beam 1 is emitted a secondary electron beam 22. The secondary electron beam 22 is detected by a secondary electron beam detector 23. The secondary electron beam detector 23 is controlled by a SEM (scanning electron microscope) controller 24. In the case of this embodiment, the SEM controller 24 comes with a video board 25 and a recording unit 26.

The video board 25 is equipped with a video processing function for SEM images and a video processing function for absorbed current images. Among them, the video processing function for SEM images includes a processing function of converting a signal detected by the secondary electron beam detector 23 into a digital signal and a processing function of displaying a SEM image on the display 14 in synchronization with the scanning of the primary electron beam 1.

The displaying of a detected signal of the secondary electron beam 22 on the display 14 in synchronization with the scanning of the primary electron beam 1 allows a SEM image to be formed on the display screen. Herein, the detected signal of the secondary electron beam 22 and the SEM image formed from the detected signal are recorded on the recording unit 26. The video processing function for absorbed current images is described later.

The SEM controller 24 is used not only for the processing of a video signal but also for control of the semiconductor testing device as a whole. Since a SEM image can be displayed on the display 14 by the SEM controller 24, the wiring pattern 3 on the surface of the specimen and a contacting position of the probes 4 at the wiring pattern 3 can be checked on the screen.

Next, the configuration of the device surrounding the specimen 2 as a testing target is described below. In the case of this embodiment, the specimen 2 is a semiconductor integrated circuit. For instance, a wafer on which a semiconductor integrated circuit is arranged in a matrix manner is assumed. The specimen 2 is placed fixedly on a specimen holder 27. A specimen stage 28 as a specimen base has a mechanism that can move the specimen holder 27 in three-axis directions including X axis, Y axis and Z axis. Each probe 4 coming into contact with the specimen 2 is conveyed and driven by a probe stage 29 dedicated for each. This probe stage 29 has a mechanism that can move its corresponding probe 4 in three-axis directions including X axis, Y axis and Z axis. With this mechanism, the probes 4 can be brought into contact at any region of the specimen 2. Thereby the contacting position of the probes 4 can be adjusted while checking the wiring pattern 3 formed on the surface of the specimen 2 and the probes 4 through a SEM image.

Coming the two probes 4 into contact with both ends of the wiring pattern 3 of the specimen 2 or their pads establishes a state where an unknown resistance is connected between the two probes 4. That is, the bridge circuit 11 is completed.

After the contact of these probes 4, control is performed so that the bridge circuit 11 is adjusted to a balanced state at the stage prior to the starting of irradiation with a primary electron beam 1. More specifically, the resistance value of the variable resistance 8 is controlled in accordance with the differential output signal. Herein, among four resistance values making up the bridge circuit 11, those of the fixed resistances 9 and 10 are known. Therefore, if the voltage to be applied to the fixed resistances 9 and 10 can be detected, then the resistance value of the wiring pattern 3 of the specimen 2 can be found. The balanced state of the bridge circuit 11 refers to the state where the same voltage is applied to the fixed resistances 9 and 10.

In the state not irradiated with the primary electron beam 1, voltage (voltage to be applied to the fixed resistances 9 and 10) is given to the differential input terminal of the differential amplifier 12 from each of the output ends A and B. The differential output signal of the differential amplifier 12 is amplified by an amplifier 30. The differential output signal subjected to the amplification is given to the video board 25 and an A/D converter 32. The A/D converter 32 converts the input differential output signal into a digital signal, and outputs the same to a resistance controller 31. The resistance controller 31 variable-controls the resistance value of the variable resistance 8 so that an input value (a value of the digital signal of the differential output signal) becomes zero. In the case of this embodiment, the resistance controller 31 contains conversion data for resistance values to make an input value zero in a storage region not illustrated.

The resistance controller 31 outputs conversion data corresponding to the input value to the variable resistance 8, and sets a resistance value of the variable resistance 8 at any resistance value. Herein, the storage region of the resistance controller 31 stores an initial value of the variable resistance 8, so that the resistance value of the variable resistance 8 can be set prior to supplying of a constant current from the constant current source 7. In order to enable such control of the resistance prior to application of a constant current, FIG. 2 shows a control line extending from the resistance controller 31 to the constant current source 7.

As stated above, the resistance controller 31 controls the resistance value of the variable resistance 8 to be an appropriate value prior to irradiation with the primary electron beam 1, thus controlling the bridge circuit 11 to a balanced state. Herein, reaching the balanced state means that the resistance value of the variable resistance 8 is decided as conversion data. Therefore the resistance controller 31 can calculate the resistance value (circuit parameter) of the unknown resistance connected between the probes 4. The thus calculated resistance value of the unknown resistance is stored in the storage region of the resistance controller 31 while being output externally as needed. Herein once the resistance value (circuit parameter) of the wiring pattern 3 is calculated, the resistance value of the variable resistance 8 can be automatically set so as to obtain the balanced state during the next testing or later. Further on the basis of the resistance value (circuit parameter) of the wiring pattern 3, a power source condition (the constant current source 7 or a constant voltage source) that can avoid breaking of the faulty part 6 can be set.

When the bridge circuit 11 is controlled to a balanced state, then the device becomes the ready state where the specimen 2 can be irradiated with the primary electron beam 1. Notification on permission indicating the ready state for the irradiation with the primary electron beam 1 is given from the resistance controller 31 to the SEM controller 24 via a signal line not illustrated. Upon receipt of the permission notification, the SEM controller 24 controlling the semiconductor testing device as a whole starts the irradiation with the primary electron beam 1 and the scanning control thereof.

The primary electron beam 1 is scanned along the surface of the specimen 2. When the irradiation position of the primary electron beam 1 is located on the wiring pattern 3 (including the faulty part 6), a part of electrons from the primary electron beam 1 enters into the wiring pattern 3 (including the faulty part 6). These electrons are detected by each of the two probes 4 as absorbed current. As stated above, the primary electron beam 1 is divided in accordance with the resistance value from the irradiation position to the probe 4, and is output from each probe 4 as absorbed current.

Such flowing-in of the absorbed current disrupts the balanced state of the bridge circuit 11, and then a non-zero differential signal is given to the differential input end of the differential amplifier 12. At the differential output end of the differential amplifier 12 appears a differential output signal that is an amplified differential signal. This differential output signal is amplified by the amplifier 30 at an amplification rate required for display of the absorbed current image 13, and is given to the video board 25. Thereafter the video board 25 gives the signal input from the differential amplifier 12 together with a signal depending on the scanning of the electron beam irradiation optical system to the display 14, to cause the display 14 to display the absorbed current image 13 on its display screen.

During this display, when the faulty part 6 of the wiring pattern 3 is irradiated with the primary electron beam 1, the resistance value of the faulty part 6 varies slightly due to thermal energy of the primary electron beam 1. Such a variation in resistance value causes current flowing through the faulty part 6 also to vary slightly. Such variations in resistance and in current are different from the magnitude of the variation in the wiring pattern 3 other than the faulty part 6. Therefore, a signal clearly different from other regions of the wiring pattern 3 is given from the bridge circuit 11 to the differential amplifier 12. As a result, at the differential output end of the differential amplifier 12 appears a differential output signal with an amplitude different from that of other regions of the wiring pattern 3. In this way, on the display screen of the display 14 is displayed an absorbed current image 15 representing the faulty part 6 of the wiring pattern 3 in an emphasized manner. That is, the absorbed current image 15 is displayed so as to emphasize a contrasting difference more than in other regions of the wiring pattern 3.

As described above, the semiconductor testing device according to this embodiment uses the resistance of the wiring pattern 3 connected to the two probes 4 as unknown resistance in the bridge circuit 11, and emphasizes a slight difference or change in resistance value at the faulty part 6 as a change of the resistance ratio of the resistances making up the bridge circuit 11 so as to be reflected to a differential input signal. As a result, a slight change in resistance can be detected in an emphasized manner not only for between the wiring pattern 3 and other regions but also in the wiring pattern 3. That is, a part of the wiring pattern 3 other than the faulty part 6 (absorbed current image 13) and a part of the wiring pattern at the faulty part 6 (absorbed current image 15) can be displayed distinguishably.

Such display of the absorbed current images facilitates the analysis of a high-resistance fault, a low-resistance fault and a short-circuit fault. In the case of a fault in wiring pattern due to bonding of different types of metal as well, a change in the Seebeck effect during irradiation of the faulty part 6 with the primary electron beam 1 is emphasized as a change of the resistance ratio of the resistances making up the bridge circuit 11 so as to be reflected to the differential input signal. In this way, a part of the wiring pattern 3 other than the faulty part 6 (absorbed current image 13) and a part of the wiring pattern at the faulty part 6 (absorbed current image 15) can be displayed distinguishably.

In this way, the semiconductor testing device according to this embodiment can remarkably improve the efficiency for faulty analysis of the wiring pattern 3.

In the case of the semiconductor testing device according to this embodiment as well, multiple faulty parts 6 can be observed at a time. Therefore in the case of the device according to this embodiment, there is no need to increase the frequency of observations in accordance with the number of faulty parts. This can alleviate the complexity of the testing, meaning that the efficiency for faulty analysis and the convenience can be improved at the same time.

Further in the case of the device according to this embodiment, circuit parameters including the resistance value of the variable resistance 8 can be automatically set in accordance with conditions letting the bridge circuit 11 operate in a balanced state. As a result, the complexity of setting during measurement can be alleviated, and the convenience can be greatly improved.

### Embodiment 3

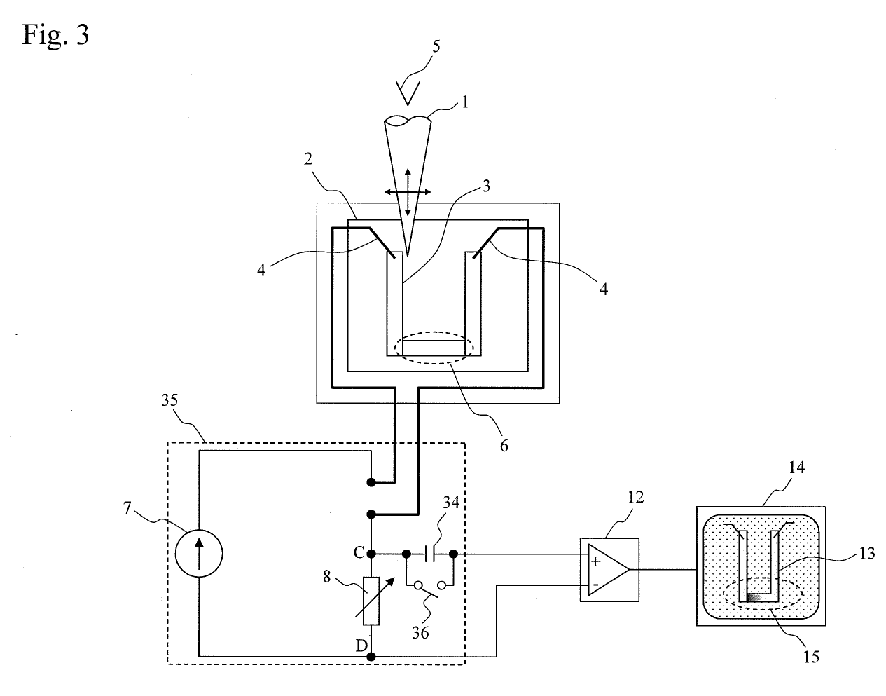

FIG. 3 schematically shows another exemplary configuration of the specimen testing device. In FIG. 3, the same reference numerals are assigned to elements common to those in FIG. 1. The specimen testing device according to this embodiment also corresponds to a type using a differential amplifier to generate an electron beam absorbed current (EBAC) image.

As shown in FIG. 3, the device according to this embodiment uses a resistance variation detection circuit 35 to detect a change in resistance (unknown resistance) of the wiring pattern 3 in contact with two probes 4. The resistance variation detection circuit 35 shown in FIG. 3 is configured as a closed circuit so that resistance (unknown resistance) of the wiring pattern 3 in contact with the two probes 4 and a variable resistance 8 are connected in series with a constant current source 7. A voltage generated across the variable resistance 8 is used as a differential input signal for a differential amplifier 12. Although FIG. 3 shows the circuit configuration including the constant current source 7 connected, a constant voltage source may be connected instead of the constant current source, similarly to Embodiments 1 and 2.

The resistance (unknown resistance) of the wiring pattern 3 and the variable resistance 8 make up a series circuit. Therefore, in this example where constant current is supplied from the constant current source 7, a voltage as the product of the resistance value of the variable resistance 8 and the flowing current appears across the variable resistance 8. Note that, when a constant voltage source is used, a voltage divided with the resistance ratio of the resistance (unknown resistance) of the wiring pattern 3 and the variable resistance 8 appears across the variable resistance 8.

In the case of this embodiment, the resistance value (circuit parameter) of the wiring pattern 3 can be calculated as follows. Herein the calculation processing may be performed by a computer or through arithmetic processing by a signal processing unit, which is not illustrated. For instance, when the constant current source 7 is used as the power supply, the voltage across the series circuit (made up of the resistance of the wiring pattern 3 and the variable resistance 8) is measured. This voltage is divided by a known current value, whereby a synthetic resistance value of the series circuit can be found. In the case of a series circuit, the synthetic resistance is given as the sum of the resistances. Therefore, the resistance value of the variable resistance 8 is subtracted from the synthetic resistance, whereby the resistance of the wiring pattern 3 can be calculated. On the other hand, when a constant voltage source is used as the power supply, voltage generated across the variable resistance 8 is measured. This measurement value is divided by the resistance value (known) of the variable resistance 8, whereby a value of the current flowing through the series circuit can be found. Alternatively, the measurement value is subtracted from the voltage (known) across the series circuit, whereby a voltage value generated across the resistance of the wiring pattern 3 can be calculated. Then, the thus calculated voltage value may be divided by the current value, whereby the resistance of the wiring pattern 3 can be calculated.

In the case of this embodiment, a connection midpoint C between the resistance (unknown resistance) of the wiring pattern 3 and the variable resistance 8 is connected to a non-inverting input end of the differential amplifier 12, and the other end D of the variable resistance 8 is connected to an inverting input end of the differential amplifier 12. Herein, to the wiring extending to the non-inverting input end is connected in series a parallel circuit made up of a capacitor 34 and a switch 36. When the switch 36 is closed, the electric potential at the connection midpoint C between the resistance of the wiring pattern 3 and the variable resistance 8 is directly given to the non-inverting input end. On the other hand, when the switch 36 is open, a change (AC component) only in electric potential at the connection midpoint C between the resistance of the wiring pattern 3 and the variable resistance 8 is given to the non-inverting input end.

In the following description, the state where the two probes 4 come into contact at a predetermined position of the specimen 2 but the specimen 2 is not yet irradiated with the primary electron beam 1 is called an initial state. In the case of the initial state, a constant voltage appears across the variable resistance 8. A differential output signal corresponding to this voltage is given to a display 14 from a differential amplifier 12 via an image processing unit not illustrated. Note that in the case of usage when the switch 36 is closed, an image of uniform brightness corresponding to the voltage appearing across the variable resistance 8 will be displayed. On the other hand, in the case of usage when the switch 36 is open, since the voltage across the variable resistance 8 is constant, the electric potential difference at the differential input end becomes zero.

Next, the case of irradiation of the wiring pattern 3 with the primary electron beam 1 is assumed. In this case, a part of electrons from the primary electron beam 1 enters into the wiring pattern 3. These entering electrons are divided in accordance with the resistance value from the irradiation position of the primary electron beam 1 to each probe 4, which is then output as absorbed current from each probe 4. In the case of FIG. 3, the absorbed current is superimposed to the current supplied from the constant current source 7. The voltage generated at the variable resistance 8 changes from the initial state by the amount corresponding to the superimposed absorbed current. In this way, a region where the voltage of the variable resistance 8 changes from the initial state is displayed on the screen as an absorbed current image 13. Herein when the switch 36 is open, out of the wiring pattern 3, the outline part of the wiring pattern 3 extending in the direction orthogonal to the scanning direction of the primary electron beam 1 is displayed on the screen.

Next, the case of irradiation of the faulty part 6 in the wiring pattern 3 with the primary electron beam 1 is described below. In this case, as described in Embodiment 1, a temporal electromotive force will be observed at the failure part 6 due to a temporal increase in resistance value resulting from heating by thermal energy of the primary electron beam 1 or the Seebeck effect.

Herein, the faulty part 6 is a local part in the wiring pattern 3. Further, the faulty part 6 has a resistance value greatly different from that of other regions of the wiring pattern 3 (regions not including a faulty part). Therefore a change in resistance value at the faulty part 6 appears as a change in the absorbed current flowing through the wiring pattern 3 or in resistance value. That is, the resistance ratio between the wiring pattern 3 and the variable resistance 8 changes.

As a result, voltage is generated across the variable resistance 8, the voltage being different from the case of irradiation of other regions (regions not including a faulty part) of the wiring pattern 3 with the primary electron beam 1. Therefore, at the differential output end of the differential amplifier 12 appears a differential output signal that is different from the case of irradiation of the wiring pattern 3 with the primary electron beam 1. Accordingly, an absorbed current image 15 corresponding to the failure part 6 having a large contrasting difference than the absorbed current image 13 of the corresponding wiring pattern 3 is displayed on the display screen. That is, the faulty part 6 can be displayed in an emphasized manner compared with other regions of the wiring pattern 3. Accordingly, the faulty part 6 can be easily identified on the detection screen.

Needless to say, in the case of this embodiment as well, a detection signal will change in the same way corresponding to the faulty part 6. Accordingly, even when there are multiple faulty parts 6 in the specimen 2, the display corresponding to the number of the faults existing can be obtained. That is, scanning once with the primary electron beam 1 enables the simultaneous detection of multiple faulty parts 6.

Similarly to the above Embodiment 1, in this embodiment also, a faulty part 6 of the wiring pattern 3 located at a position away from the surface of the specimen (deeper position) can be easily identified. Further similarly to the above Embodiment 1, in this embodiment also, the faulty part 6 and the wiring pattern 3 may be displayed using not different contrasts but different display colors. Further signal processing may be added by an image processing unit not illustrated so that a difference in detected signal between the faulty part 6 and other regions of the wiring pattern 3 is emphasized.

### Embodiment 4

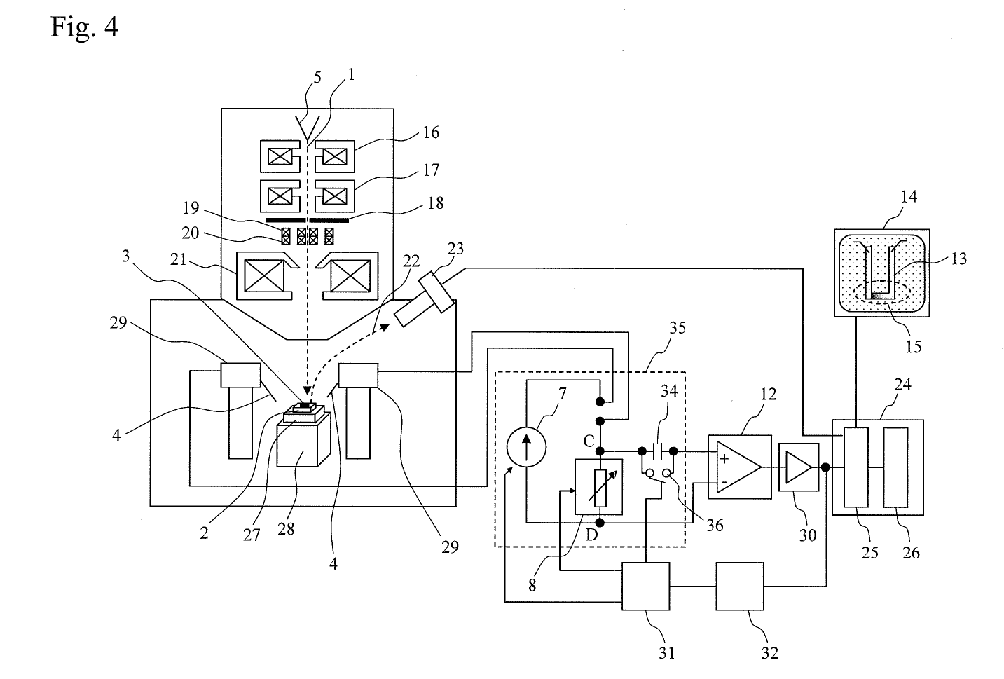

FIG. 4 shows an exemplary configuration of a semiconductor testing device including the specimen testing device according to Embodiment 3. In FIG. 4, the same reference numerals are assigned to elements common to those in FIG. 2 (Embodiment 2). The following mainly describes a difference from Embodiment 2, especially a control operation relating to the resistance variation detection circuit 35.

The following is based on the assumption that the two probes 4 are already in contact with both ends of the wiring pattern 3 of the specimen 2 or their pads. That is, the resistance variation detection circuit 35 becomes an operable state.

Prior to the starting of irradiation with primary electron beam 1, the resistance value of the variable resistance 8 is set at the initial value. The resistance controller 31 holds the initial values for the constant current source 7 and the variable resistance 8, and such an initial value is set via the resistance controller 31.

When a constant voltage source is used for the power supply, following the initial setting, the switch 36 is controlled to be closed via the resistance controller 31, whereby the resistance value of the wiring pattern 3 can be calculated. When the switch 36 is controlled to be closed, the circuit may have a configuration not using the capacitor 34. In this case, the voltage generated across the variable resistance 8 can be detected. The voltage generated across the variable resistance 8 is input to the resistance controller 31 via the amplifier 30 and the A/D converter 32. Herein the resistance controller 31 knows all of the voltage value of the constant voltage supply, the resistance value of the variable resistance 8 and the gain of the amplifier 30. Therefore using these known values and the output value from the amplifier 30, the resistance controller 31 can calculate the resistance value of the wiring pattern 3.

On the other hand, when the constant current source 7 is used as the power supply, detecting voltage generated across the wiring pattern 3 and the variable resistance 8 enables the calculation of the resistance value (circuit parameter) of the wiring pattern 3. In this way, if the resistance value of the wiring pattern 3 can be calculated, then the resistance value of the variable resistance 8 can be automatically set so as to obtain the resistance ratio suitable for detection.

Referring back to FIG. 4, after the above-mentioned initial setting operation is finished, the resistance controller 31 controls the switch 36 to be open. That is, the circuit configuration using the capacitor 34 is selected. In this case, at the non-inverting input end of the differential amplifier 12 is input a variation (AC component) only of the voltage generated across the variable resistance 8.

At this time, the constant current source 7 supplies constant current to the wiring pattern 3 and the variable resistance 8. In this state, when the wiring pattern 3 is irradiated with the primary electron beam 1, absorbed current is superimposed to the constant current supplied from the constant current source 7. At the starting and ending of the superimposition of this absorbed current, the voltage generated across the variable resistance 8 changes. At this time, a differential output voltage corresponding to this change is given to the amplifier 30 from the differential amplifier 12, and the display 14 displays an absorbed current image 13 giving the outline of the wiring pattern 3.

Next, it is assumed that the faulty part 6 of the wiring pattern 3 is irradiated with the primary electron beam 1. In this case, the resistance value of the faulty part 6 greatly changes due to thermal energy of the primary electron beam 1, and the absorbed current flowing through the wiring pattern 3 varies. When the absorbed current varies, the resistance value of the wiring pattern 3 also changes. Then, the resistance ratio of the resistance of the wiring pattern 3 and the variable resistance 8 changes more than the case of irradiation of a region other than the faulty part 6 of the wiring pattern 3 with the primary electron beam 1. As a result, the voltage generated across the variable resistance 8 changes relatively greatly. Herein, when the resistance value changes with the irradiation position of the primary electron beam 1 with reference to the faulty part 6, a change in voltage occurring with the movement of the irradiation position of the primary electron beam 1 is given to the amplifier 30 from the differential amplifier 12 as a differential output voltage. As a result, the display 14 displays an absorbed current image 15 giving the faulty part and the outline of the wiring pattern 3.

As described above, the semiconductor testing device according to this embodiment uses the resistance of the wiring pattern 3 connected to the two probes 4 as unknown resistance in the resistance variation detection circuit 35, and emphasizes a slight difference or change of the resistance value between the faulty part 6 and other regions of the wiring pattern 3 so as to be reflected to a differential input signal. As a result, a slight change in resistance can be detected in an emphasized manner not only for between the wiring pattern 3 and other regions but also in the wiring pattern 3. That is, a part of the wiring pattern 3 other than the faulty part 6 (absorbed current image 13) and a part of the wiring pattern at the faulty part 6 (absorbed current image 15) can be displayed distinguishably.

Such display of the absorbed current images facilitates the analysis of a high-resistance fault, a low-resistance fault and a short-circuit fault. In the case of a fault in wiring pattern due to bonding of different types of metal as well, a change in the Seebeck effect during irradiation of the faulty part 6 with the primary electron beam 1 is emphasized as a change of the resistance ratio of the wiring pattern 3 and the variable resistance 8 so as to be reflected to the differential input signal. In this way, a part of the wiring pattern 3 other than the faulty part 6 (absorbed current image 13) and a part of the wiring pattern at the faulty part 6 (absorbed current image 15) can be displayed distinguishably.

In the case of the semiconductor testing device according to this embodiment as well, multiple faulty parts 6 can be observed at a time. Therefore in the case of the device according to this embodiment, there is no need to increase the frequency of observations in accordance with the number of faulty parts. This can alleviate the complexity of the testing, meaning that the efficiency for faulty analysis and the convenience can be improved at the same time.

Further, in the case of the device according to this embodiment, circuit parameters including the resistance value of the variable resistance 8 can be automatically set beforehand. Accordingly, the complexity of setting during measurement can be alleviated, and the convenience can be greatly improved.

### DESCRIPTION OF REFERENCE NUMBERS

1: Primary electron beam
2. Specimen
3: Wiring pattern
4: Probe
5: Electron beam source
6: Faulty part
7: Constant current source
8: Variable resistance
9: Fixed resistance
10: Fixed resistance
11: Bridge circuit
12: Differential amplifier
13: Absorbed current image
14: Display
15: Absorbed current image (faulty part)
16, 17: Condenser lens
18: Diaphragm
19: Scanning deflector
20: Image shift deflector
21: Objective lens
22: Secondary electron beam
23: Secondary electron beam detector
24: SEM controller
25: Video board
26: Recording unit
27: Specimen holder
28: Specimen stage
29: Probe stage
30: Amplifier
31: Resistance controller
32: A/D converter
34: Capacitor
35: Resistance variation detection circuit
36: Switch

1. A specimen testing device, comprising:
a specimen base on which a specimen can be placed;
an electron beam irradiation optical system enabling the specimen to be irradiated with an electron beam;
at least two probes that are in contact with the specimen;
a bridge circuit that uses, as unknown resistance, a wiring section specified by a contact of the two probes with the specimen;
a differential amplifier that receives, as an input, a signal from two points on the bridge circuit where an equipotential appears in a balanced state;
an image processing unit that outputs an absorbed current image on a basis of a differential output signal appearing at the differential amplifier in response to scanning of an electron beam to the specimen and a signal to control scanning of the electron beam; and
a display that displays the absorbed current image.

2. The specimen testing device according to claim 1, wherein the specimen is a semiconductor specimen including a wiring pattern formed therein.

3. The specimen testing device according to claim 1, wherein a circuit parameter of the wiring section is calculated by arithmetic processing using a known resistance value of the bridge circuit.

4. A method for creating an absorbed current image using a specimen testing device including: a specimen base on which a specimen can be placed; an electron beam irradiation optical system enabling the specimen to be irradiated with an electron beam; and at least two probes that are in contact with the specimen, the method comprising the steps of:
controlling a bridge circuit to be a balanced state, the bridge circuit using, as unknown resistance, a wiring section specified by a contact of the two probes with the specimen;
inputting, to a differential amplifier, a signal from two points on the bridge circuit where an equipotential appears in a balanced state;
outputting an absorbed current image on a basis of a differential output signal appearing at the differential amplifier in response to scanning of an electron beam to the specimen and a signal to control scanning of the electron beam; and
displaying the absorbed current image.

5. A specimen testing device, comprising:
a specimen base on which a specimen can be placed;
an electron beam irradiation optical system enabling the specimen to be irradiated with an electron beam;
at least two probes that are in contact with the specimen;
a detection circuit that includes a resistance connected in series with a wiring section specified by a contact of the two probes with the specimen and a constant current source or a constant voltage source that supplies constant current or constant voltage to the resistance and the wiring section, the detection circuit detecting a signal appearing at a connection midpoint between the resistance and the wiring section;
an element that removes a DC component from the detected signal;
a differential amplifier that receives, as an input, the detected signal after removal of the DC component and a reference signal;
an image processing unit that outputs an absorbed current image on a basis of a differential output signal appearing at the differential amplifier in response to scanning of an electron beam to the specimen and a signal to control scanning of the electron beam; and
a display that displays the absorbed current image.

6. The specimen testing device according to claim 5, further comprising switching means that switches one of inputs to the differential amplifier between the detected signal after removal of the DC component and the detected signal before removal of the DC component.

7. The specimen testing device according to claim 5, wherein the resistance is a variable resistance.

8. The specimen testing device according to claim 5, wherein the specimen is a semiconductor specimen including a wiring pattern formed therein.

9. The specimen testing device according to claim 5, wherein a circuit parameter of the wiring section is calculated by arithmetic processing using a resistance value of the resistance and a differential output signal appearing at the differential amplifier.

10. A method for creating an absorbed current image using a specimen testing device including: a specimen base on which a specimen can be placed; an electron beam irradiation optical system enabling the specimen to be irradiated with an electron beam; and at least two probes that are in contact with the specimen,
wherein the specimen testing device includes a detection circuit that includes a resistance connected in series with a wiring section specified by a contact of the two probes with the specimen and a constant current source or a constant voltage source that supplies constant current or constant voltage to the resistance and the wiring section, the method comprising the steps of:
inputting, as a detection signal, a signal appearing at a connection midpoint between the resistance and the wiring section to an element that removes a DC component;
inputting, to a differential amplifier, the detection signal after removal of the DC component and a reference signal;
outputting an absorbed current image on a basis of a differential output signal appearing at the differential amplifier in response to scanning of an electron beam to the specimen and a signal to control scanning of the electron beam; and
displaying the absorbed current image.

11. The specimen testing device according to claim 2, wherein a circuit parameter of the wiring section is calculated by arithmetic processing using a known resistance value of the bridge circuit.

12. The specimen testing device according to claim 6, wherein the resistance is a variable resistance.

13. The specimen testing device according to claim 6, wherein the specimen is a semiconductor specimen including a wiring pattern formed therein.

14. The specimen testing device according to claim 6, wherein a circuit parameter of the wiring section is calculated by arithmetic processing using a resistance value of the resistance and a differential output signal appearing at the differential amplifier.
